(19) United States
(12) Patent Application Publication
(10) Pub. No.: US 2025/0192671 A1
(43) Pub. Date: Jun. 12, 2025

(54) Zero Cross Solid State Relay with EMI Filter Capacitors

(71) Applicant: TE Connectivity Solutions GmbH, Schaffhausen (CH)

(72) Inventors: Tien Duc NGO, West Covina, CA (US); Brandon BUSS, Oxnard, CA (US); David MARKLE, Carpinteria, CA (US)

(73) Assignee: TE Connectivity Solutions GmbH, Schaffhausen (CH)

(21) Appl. No.: 18/916,823

(22) Filed: Oct. 16, 2024

Related U.S. Application Data
(60) Provisional application No. 63/607,186, filed on Dec. 7, 2023.

(51) Int. Cl. H02M 1/44; H02M 1/08; H02M 7/219

(52) U.S. Cl. CPC H02M 1/44; H02M 1/083; H02M 7/219

(57) ABSTRACT

A solenoid valve having a solenoid body with a solenoid receiving cavity and a flow receiving passage. A solenoid assembly is provided in the solenoid receiving cavity. A valve is provided in the flow receiving passage. An armature extends from the solenoid to the valve. The solenoid valve also includes a control circuitry, a power connection and a bidirectional communications connection. At least one sensor is provided in the flow receiving passage. The at least one sensor is in communication with the control circuitry. When in operation, power is continuously supplied through the power connection and the actuation of the solenoid valve is initiated by the bidirectional communications connection.

### FIELD OF THE INVENTION

The present invention relates to a zero cross solid state relay with electromagnetic interference (EMI) filter capacitors. In particular, the invention relates to solid state relay which reduces electromagnetic interference when the relay is conducting current.

### BACKGROUND OF THE INVENTION

Since their introduction over three decades ago, solid state relays (SSRs) have displaced electromagnetic relays (EMRs) for switching applications demanding ultra-reliable, arc-free, low-power operation. Such SSRs reduce noise during operation and are compatible with digital control circuits. One such solid state relay is a zero cross solid state relay, in which switching the power component only takes place at close to zero volts. This limits disturbances on the network and increase the service life of the load and the relay.

While known zero cross solid-state relays work well in many applications, it is not possible for the zero cross circuit to turn on an SCR at 0V, When SCR is turned on at 10-15V, an inrush current is produced which creates higher conducted emission to the line. In demanding home, commercial and medical applications—particularly those where adherence to international electromagnetic compatibility (EMC) standards—many known zero cross solid state relays do not adequately reduce or minimize the electromagnetic interference (EMI) generated by the relay to meet the needs of the application. In particular, in applications in which the size of the zero cross solid state relay must be minimized, known zero cross solid state relays cannot provide the EMI filtering required.

It would, therefore, be desirable to provide a zero cross solid state relay which overcomes the issues associated with the known art. In particular, it would be beneficial to provide a reduced size zero cross solid state relay with EMI filter capacitors which reduces electromagnetic interference when the relay is conducting current.

### SUMMARY OF THE INVENTION

It is an object to provide a reduced size zero cross solid state relay with EMI filter capacitors which reduces electromagnetic interference when the relay is conducting current.

An embodiment is directed to a zero cross circuit having a first section and an EMI filter section. The EMI filter section is turned on only when the first section is conducting current. One or more capacitors are provided on the EMI filter section.

In an embodiment, a current transformer is provided on the EMI filter section. The current transformer is activated when the current transformer senses current from the first section.

In an embodiment, a rectifier bridge is provided on the EMI filter section in line with the current transformer. One or more field-effect transistors may be provided on the EMI filter section in line with the rectifier bridge. The one or more capacitors may be provided on the EMI filter section in line with the one or more field-effect transistors. One or more resistors and one or more capacitors may be provided between the rectifier bridge and the one or more field-effect transistors.

An embodiment is directed to a method of reducing electromagnetic interference on a zero cross circuit, the method comprising: determining if current is being conducted across a first section of the zero cross circuit; and turning on an EMI filter section of the zero cross circuit if it is determined that current is being conducted across the first section; or turning off an EMI filter section of the zero cross circuit if it is determined that current is not being conducted across the first section.

In an embodiment, a current transformer is provided on the EMI filter section. The current transformer is activated when the current transformer senses current from the first section. A rectifier bridge is provided on the EMI filter section in line with the current transformer, the rectifier bridge converting alternating current from the current transformer to direct current. One or more capacitors are provided on the EMI filter section in line with the one or more field-effect transistors, the capacitors directing high frequency noise through a low impedance path to ground.

Other features and advantages of the present invention will be apparent from the following more detailed description of the illustrative embodiment, taken in conjunction with the accompanying drawings which illustrate, by way of example, the principles of the invention.

### BRIEF DESCRIPTION OF THE DRAWINGS

FIG. 1 is a schematic diagram of a first embodiment of a zero cross solid state relay with EMI filter capacitors according to the present invention.

FIG. 2 is a schematic diagram of a second embodiment of a zero cross solid state relay with EMI filter capacitors according to the present invention.

### DETAILED DESCRIPTION OF THE INVENTION

The description of illustrative embodiments according to principles of the present invention is intended to be read in connection with the accompanying drawings, which are to be considered part of the entire written description. In the description of embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise.

Moreover, the features and benefits of the invention are illustrated by reference to the preferred embodiments. Accordingly, the invention expressly should not be limited to such embodiments illustrating some possible non-limiting combination of features that may exist alone or in other combinations of features, the scope of the invention being defined by the claims appended hereto.

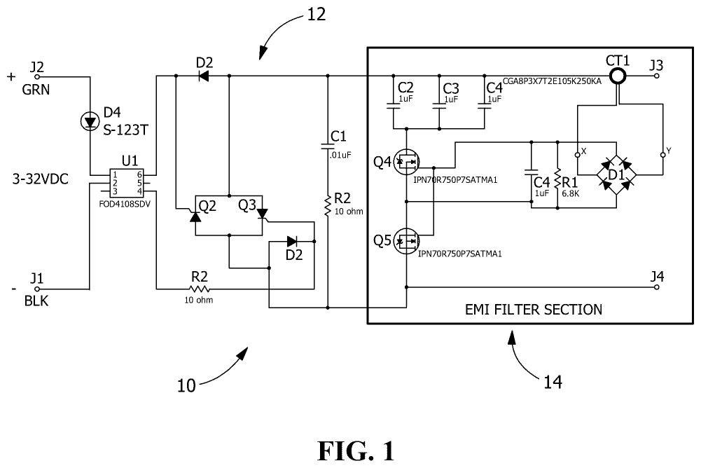

As shown in FIG. 1, a first embodiment of the zero cross circuit 10 has a first section 12 and a second or EMI filter section 14. The circuit 10 has a start and end point J1, J2 which delivers AC power to the circuit 10.

The first section 12 of the zero cross circuit 10 includes a current regulator diode D4, such as, but not limited to Semitec 50V, 12 mA diode. An optoisolator U1 is provided in line with the diode D4 such that when the input current is applied to the optoisolator, infrared light is produced and passes through the material inside the optoisolator. The beam travels across a transparent gap and is picked up by the receiver, which acts as a converter. Using signal isolation, the sensor is able to transform the modulated light back into an output signal. The optoisolator may be, but is not limited to, ON Semiconductor optoisolator 5 kV Triac 6 SMD.

The first section 12 of the zero cross circuit 10 also includes diodes D2, D3, step recovery diodes Q2, Q3, resistors R2, R3 and a capacitor C1. The diodes D2, D3 may be, but are not limited to, Central Semiconductor Corp. CMHD3595TR diodes. The resistors R2, R3 may be, but are not limited to, Stackpole Electronics Inc. 10 OHM 5% ¼ W 0805 resistors. The capacitor C1 may be, but is not limited to, Knowles Syfer 0.01 μF, 1.5 kV capacitor.

The second or EMI filter section 14 of the zero cross circuit 10 includes a current transformer CT1. The current transformer CT1 is activated when it senses a current from the first section 12 of the zero cross circuit 10. The current transformer CT1 produces an alternating current in its secondary winding which is proportional to the current being measured in its primary, thereby reducing high voltage currents to a much lower value.

A diamond shaped rectifier bridge D1 is provided in line with the current transformer CT1. In the embodiment shown, the rectifier bridge D1 has four diodes. The rectifier bridge D1 converts the lower voltage alternating current to direct current. The rectifier bridge D1 may be, but is not limited to, ON Semiconductor IC Bridge Rect 0.5 A 100V 4-SOIC.

The output of the rectifier bridge D1 is directed to a resistor R1, a capacitor C5 and field-effect transistors (FET) or metal-oxide-semiconductor field-effect transistors (MOSFET) Q4, Q5. The resistor R1 may be, but is not limited to, Panasonic Electronic Component 6.81K Ohm 1% ⅛ W Resistor. The capacitor C5 may be, but is not limited to, Kemet 1 μF capacitor. The FETS or MOSFETs Q4, Q5 have high switching speeds and good efficiency at low voltages. The FETS or MOSFETs Q4, Q5 may be, but are not limited to, Infineon Technologies COOLMOS P7 800V SOT-223.

Capacitors C2, C3, C4 are provided on the EMI filter section 14 of the zero cross solid state relay 10. The capacitors C2, C3, C4 direct high-frequency noise through a low-impedance path back to the power-supply ground or system ground. The capacitors C2, C3, C4 may be, but are not limited to TDK Corporation CAP CER 1UF 250V X7T 1812.

In operation, when the optoisolator U1 of the first section 12 of the zero cross circuit 10 receives current, the zero cross circuit waits until the current half-cycle is complete. At the zero-cross point, the optoisolator U1 supplies current to the current transformer CT1 in the EMI filter section 14 of the zero cross circuit 10.

As stated above, the current transformer CT1 produces an alternating current in its secondary winding which is proportional to the current being measured in its primary, thereby reducing high voltage currents to a much lower value. The lower voltage current is then supplied to the rectifier bridge D1. The rectifier bridge D1 then converts the lower voltage alternating current to direct current.

In the illustrative embodiment shown the direct current is supplied to the capacitors C2, C3, C4 through the resistor R1, the capacitor C5 and the field-effect transistors Q4, Q5. However, other configuration and other devices may be used. In addition, the number of capacitors may vary depending upon the application. The capacitors C2, C3, C4 are configured to remove high-frequency noise from the circuit 10.

The EMI filter section 14 of the zero cross circuit 10 is activated only during time of high current. As the capacitors C2, C3, C4 are activated by the current transformer CT1 and the rectifier bridge D1, smaller size capacitors can be used. This allows the entire circuit 10 to be reduced in size. For example, the circuit 10 can be reduced to less than one square inch to a load of 480V AC.

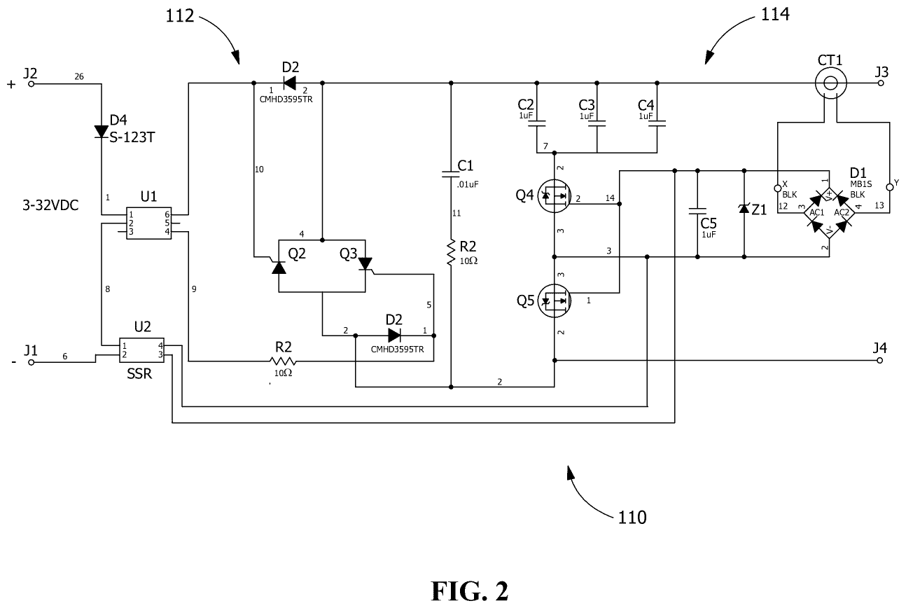

FIG. 2, a second embodiment of the zero cross circuit 110 has a first section 112 and a second or EMI filter section 114. The circuit 110 has a start and end point J1, J2 which delivers AC power to the circuit 110.

The first section 112 of the zero cross solid circuit 110 includes a current regulator diode D4, such as, but not limited to Semitec 50V, 12 mA diode. An optoisolator U1 is provided in line with the diode D4 such that when the input current is applied to the optoisolator, infrared light is produced and passes through the material inside the optoisolator. The beam travels across a transparent gap and is picked up by the receiver, which acts as a converter. Using signal isolation, the sensor is able to transform the modulated light back into an output signal. The optoisolator may be, but is not limited to, ON Semiconductor optoisolator 5 kV Triac 6 SMD.

A solid state relay U2 is provided in line with the optoisolator U1. The solid state relay U2. The solid state relay U2 may be, but is not limited to, COTO Technology MOS Opto N.C SSR.

The first section 112 of the zero cross circuit 110 also includes diodes D2, D3, step recovery diodes Q2, Q3, resistors R2, R3 and a capacitor C1. The diodes D2, D3 may be, but are not limited to, Micro Commercial Co. 1000V diodes. The resistors R2, R3 may be, but are not limited to, Stackpole Electronics Inc. 10 OHM ½ W 0805 resistors. The capacitor C1 may be, but is not limited to, Knowles Syfer 0.01 μF, 1.5 kV capacitor.

The second or EMI filter section 114 of the zero cross circuit 110 includes a current transformer CT1. The current transformer CT1 is activated when it senses a current from the first section 112 of the zero cross circuit 110. The current transformer CT1 produces an alternating current in its secondary winding which is proportional to the current being measured in its primary, thereby reducing high voltage currents to a much lower value.

A diamond shaped rectifier bridge D1 is provided in line with the current transformer CT1. In the embodiment shown, the rectifier bridge D1 has four diodes. The rectifier bridge D1 converts the lower voltage alternating current to direct current. The rectifier bridge D1 may be, but is not limited to, ON Semiconductor IC Bridge Rect 0.5 A 100V 4-SOIC.

The output of the rectifier bridge D1 is directed to a Zener diode Z1, a capacitor C5 and field-effect transistors (FET) or metal-oxide-semiconductor field-effect transistors (MOSFET) Q4, Q5. The Zener diode Z1 may be, but is not limited to, Diodes Incorporated 8.24V 500 MW Zener diode. The capacitor C5 may be, but is not limited to, Yageo 1 μF 250V capacitor. The FETS or MOSFETs Q4, Q5 have high switching speeds and good efficiency at low voltages. The FETS or MOSFETs Q4, Q5 may be, but are not limited to, Infineon Technologies COOLMOS P7 800V SOT-223.

Capacitors C2, C3, C4 are provided on the EMI filter section 114 of the zero cross circuit 10. The capacitors C2, C3, C4 direct high-frequency noise through a low-impedance path back to the power-supply ground or system ground. The capacitors C2, C3, C4 may be, but are not limited to TDK Corporation 1 μF 250V capacitors.

In operation, when the optoisolator U1 of the first section 112 of the zero cross circuit 110 receives current, the zero cross circuit waits until the current half-cycle is complete. At the zero-cross point, the optoisolator U1 supplies current to the current transformer CT1 in the EMI filter section 114 of the zero cross circuit 110.

As stated above, the current transformer CT1 produces an alternating current in its secondary winding which is proportional to the current being measured in its primary, thereby reducing high voltage currents to a much lower value. The lower voltage current is then supplied to the rectifier bridge D1. The rectifier bridge D1 then converts the lower voltage alternating current to direct current.

In the illustrative embodiment shown the direct current is supplied to the capacitors C2, C3, C4 through the Zener diode Z1, the capacitor C5 and the field-effect transistors Q4, Q5. However, other configuration and other devices may be used. In addition, the number of capacitors may vary depending upon the application. The capacitors C2, C3, C4 are configured to remove high-frequency noise from the circuit 110.

The EMI filter section 114 of the zero cross circuit 110 is activated only during time of high current. As the capacitors C2, C3, C4 are activated by the current transformer CT1 and the rectifier bridge D1, smaller size capacitors can be used. This allows the entire circuit 110 to be reduced in size. For example, the circuit 10 can be reduced to less than one square inch to a load of 480V AC.

While the invention has been described with reference to a preferred embodiment, it will be understood by those skilled in the art that various changes may be made and equivalents may be substituted for elements thereof without departing from the spirit and scope of the invention as defined in the accompanying claims. One skilled in the art will appreciate that the invention may be used with many modifications of structure, arrangement, proportions, sizes, materials and components and otherwise used in the practice of the invention, which are particularly adapted to specific environments and operative requirements without departing from the principles of the present invention. The presently disclosed embodiments are therefore to be considered in all respects as illustrative and not restrictive, the scope of the invention being defined by the appended claims, and not limited to the foregoing description or embodiments.

1. A zero cross circuit comprising:
a first section;
an EMI filter section;
the EMI filter section is turned on only when the first section is conducting current.

2. The zero cross circuit as recited in claim 1, wherein a current transformer is provided on the EMI filter section, the current transformer is activated when the current transformer senses current from the first section.

3. The zero cross circuit as recited in claim 2, wherein a rectifier bridge is provided on the EMI filter section in line with the current transformer.

4. The zero cross circuit as recited in claim 3, wherein one or more field-effect transistors are provided on the EMI filter section in line with the rectifier bridge.

5. The zero cross circuit as recited in claim 4, wherein one or more capacitors are provided on the EMI filter section in line with the one or more field-effect transistors.

6. The zero cross circuit as recited in claim 5, wherein one or more resistors are provided between the rectifier bridge and the one or more field-effect transistors.

7. The zero cross circuit as recited in claim 5, wherein one or more capacitors are provided between the rectifier bridge and the one or more field-effect transistors.

8. The zero cross circuit as recited in claim 5, wherein one or more diodes are provided between the rectifier bridge and the one or more field-effect transistors.

9. The zero cross circuit as recited in claim 5, wherein an optoisolator is provided on the first section.

10. The zero cross circuit as recited in claim 9, wherein one or more diodes are positioned in the first section, the one or more diodes are positioned between the optoisolator and the current transformer of the EMI filter section.

11. The zero cross circuit as recited in claim 9, wherein one or more resistors are positioned in the first section, the one or more resistors are positioned between the optoisolator and the current transformer of the EMI filter section.

12. The zero cross circuit as recited in claim 9, wherein one or more capacitors are positioned in the first section, the one or more capacitors are positioned between the optoisolator and the current transformer of the EMI filter section.

13. The zero cross circuit as recited in claim 9, wherein a solid state relay is positioned in the first section, the output of the solid state relay extending to the EMI filter section.

14. A method of reducing electromagnetic interference on a zero cross circuit, the method comprising:
determining if current is being conducted across a first section of the zero cross circuit;
turning on an EMI filter section of the zero cross circuit if it is determined that current is being conducted across the first section;
turning off an EMI filter section of the zero cross circuit if it is determined that current is not being conducted across the first section.

15. The method as recited in claim 14, wherein a current transformer is provided on the EMI filter section, the current transformer is activated when the current transformer senses current from the first section.

16. The method as recited in claim 15, wherein a rectifier bridge is provided on the EMI filter section in line with the current transformer, the rectifier bridge converting alternating current from the current transformer to direct current.

17. The method as recited in claim 16, wherein one or more field-effect transistors are provided on the EMI filter section in line with the rectifier bridge.

18. The method as recited in claim 17, wherein one or more capacitors are provided on the EMI filter section in line with the one or more field-effect transistors, the capacitors directing high frequency noise through a low impedance path to ground.

19. The method as recited in claim 13, wherein an optoisolator is provided on the first section.

20. The method as recited in claim 19, wherein a solid state relay is positioned in the first section, the output of the solid state relay extending to the EMI filter section.
